(19) United States
(12) Patent Application Publication
(10) Pub. No.: US 2015/0017344 A1
(43) Pub. Date: Jan. 15, 2015

(54) THIN FILM FORMATION

(71) Applicant: Universiteit Leiden, Leiden (NL)

(72) Inventors: Guocai Dong, Leiden (NL); Richard Van Rijn, Leiden (NL)

(21) Appl. No.: 14/375,699

(22) PCT Filed: Jan. 29, 2013
(86) PCT No.: PCT/EP2013/051701

§ 371 Date: Jul. 30, 2014

Related U.S. Application Data
(60) Provisional application No. 61/592,620, filed on Jan. 31, 2012.

(30) Foreign Application Priority Data
Jan. 31, 2012 (GB) 1201600.2

(51) Int. Cl. C23C 16/46; C23C 16/455; C23C 16/56; C23C 16/26; C23C 16/02

(52) U.S. Cl. CPC C23C 16/463; C23C 16/26; C23C 16/0227; C23C 16/56; C23C 16/45557; C23C 16/45519
USPC 427/534; 427/249.6

(57) ABSTRACT

A method of forming a graphene film (20) on one or more surfaces (10) of a copper-containing substrate (12) comprising the steps of: (i) heating a copper-containing substrate (12) defining one or more surfaces (10) to an exposure temperature; (ii) exposing the substrate (12) to a carbon-containing precursor gas at the exposure temperature for a predetermined period of time to dissolve carbon atoms into the substrate (12) and saturate the substrate (12) with carbon atoms; and (iii) cooling the substrate (12) so as to segregate the dissolved carbon atoms (16) from the substrate (12) to form a graphene film (20) on the or each surface (10) of the substrate (12); wherein the method further includes the step of selecting the copper-containing substrate (12) on the basis of its thickness to control the depth of the graphene film (20) formed on the or each surface (10) of the substrate (12) on cooling the substrate (12) so as to segregate the dissolved carbon atoms from the substrate (12).

The invention relates to a method of forming a graphene film on one or more planar surfaces of a copper-containing substrate.

Graphene has specific properties that render it compatible with a wide range of applications such as fast and flexible electronics, lasers, bio-sensors, atomically thin protective coatings, hydrogen storage and energy storage. In particular, graphene demonstrates higher carrier mobility than conventional semiconductor materials, which can be exploited to improve the speed of electronics including microprocessors.

Chemical vapour deposition (CVD) has conventionally been used to make graphene. In such methods, a surface of a metal substrate is exposed to a carbon-containing precursor gas, such as ethylene or benzene, which results in adsorption of precursor gas molecules on the surface of the metal substrate. The adsorbed precursor gas molecules then decompose to form carbon, which remain on the surface of the metal substrate to form graphene. Any volatile components are typically pumped away by a vacuum pumping system.

Methods of making graphene film using CVD typically involve the use of a metal substrate formed from nickel or copper. This is because both nickel and copper have a similar lattice structure to graphene.

A more recent development in the manufacture of graphene film has seen the use of carbon segregation in which carbon atoms are dissolved into a metal substrate and are then segregated to form a graphene film on a surface of the metal substrate. Such methods have however relied on the use of substrates formed from nickel as opposed to copper.

This is because nickel exhibits a higher solubility of carbon. This in turn allows a large number of carbon atoms to be dissolved per unit volume of nickel for segregation to form a graphene film. Copper on the other hand exhibits a relatively low solubility of carbon, approximately three orders of magnitude lower than that of nickel, which greatly reduces the number of dissolved carbon atoms per unit volume and greatly increases the time required to segregate dissolved carbon atoms to form a graphene film. Copper has therefore been considered unsuitable for use in the manufacture of graphene using carbon segregation methods.

According to an aspect of the invention there is provided a method of forming a graphene film on one or more surfaces of a copper-containing substrate comprising the steps of:
(i) heating a copper-containing substrate defining one or more surfaces to an exposure temperature;
(ii) exposing the substrate to a carbon-containing precursor gas at the exposure temperature for a predetermined period of time to dissolve carbon atoms into the substrate and saturate the substrate with carbon atoms; and
(iii) cooling the substrate so as to segregate the dissolved carbon atoms from the substrate to form a graphene film on the or each surface of the substrate;
   wherein the method further includes the step of selecting the copper-containing substrate on the basis of its thickness to control the depth of the graphene film formed on the or each surface of the substrate on cooling the substrate so as to segregate the dissolved carbon atoms from the substrate.

It was previously assumed that when carbon atoms are dissolved in a metal substrate, when the substrate is exposed to a carbon-containing precursor gas, the carbon atoms accumulate in greatest concentration towards the surface of the metal substrate that is exposed to the carbon-containing precursor gas, thereby resulting in an uneven distribution of carbon atoms dissolved in the metal substrate.

Copper has however been found to exhibit a relatively high diffusion coefficient of carbon, which results in a homogeneous and uniform distribution of carbon atoms when carbon atoms are dissolved in a copper-containing substrate. This means that any changes in the volume of the copper-containing substrate results in a directly proportional change in the number of carbon atoms that may be dissolved into the copper-containing substrate. Thus, for a given surface area and carbon solubility, the number of carbon atoms that may be dissolved into the copper-containing substrate is directly proportional to the thickness of the copper-containing substrate.

It will be appreciated that the number of carbon atoms dissolved into the copper-containing substrate is the number of carbon atoms available for subsequent segregation, which in turn determines the number of monolayers of graphene film that may be formed on the surface of the substrate. As such, the thickness of the copper-containing substrate determines the depth of the resultant graphene film formed through carbon segregation on the or each surface of the copper-containing substrate.

The diffusion coefficient of carbon in nickel has been found to be similar to that of copper, differing only roughly by a factor of 2, and hence a nickel substrate exhibits a similar homogeneous distribution of carbon atoms when carbon atoms are dissolved into the substrate as a result of exposure to a carbon-containing precursor gas.

The high solubility of carbon in nickel however renders it practically impossible to form a nickel substrate that is sufficiently thin to control the depth of a graphene film formed by segregating carbon atoms from the nickel substrate. For example, the high solubility of carbon in nickel means that a nickel substrate having a depth of only 50 nm would be required to form a monolayer of graphene on opposing sides of the nickel substrate. Not only is it nearly impossible to manufacture a freestanding film of nickel having a depth of only 50 nm, but such a film would be so fragile that it would be unlikely to withstand exposure to the temperatures likely to be encountered in carbon segregation methods. Such a thin film of nickel would, for example, be at risk of breaking up in balls on the supporting surface or of forming an alloy with the supporting surface. As a consequence, the only way to limit the depth of a graphene film formed on a nickel substrate through carbon segregation is to carefully control the exposure time and pressure of the carbon-containing precursor gas so as to limit the number of carbon atoms that are dissolved into the nickel substrate and are then subsequently available for segregation, or to carefully control the length of time of cooling of the nickel substrate so as to limit the number of carbon atoms that are segregated from the nickel substrate. It is not possible using a nickel substrate in a carbon segregation method to control the thickness of a resultant graphene film by controlling the thickness of the nickel substrate.

In contrast, the aforementioned low solubility of carbon in copper is advantageous in that it requires the use of a copper-containing substrate having macroscopic dimensions, in the order of 1 micron to 1 millimetre, in order to dissolve sufficient carbon atoms into the copper-containing substrate and enable formation of a graphene monolayer through segregation. Since the macroscopic scale is readily measurable using the naked eye, the thickness of a copper-containing substrate may be readily controlled to a high degree of accuracy. In comparison, the high solubility of carbon in nickel means that, as outlined above, a nickel substrate must have microscopic dimensions to dissolve sufficient carbon atoms to form a graphene monolayer, which in turn introduces serious difficulties in controlling the thickness of the nickel substrate.

The relationship between the thickness of the copper-containing substrate and the depth of the resultant graphene film may be used to achieve a desired depth of the graphene film on the or each surface of the copper-containing substrate. To do so, the amount of carbon atoms per unit area in a graphene monolayer formed on the or each surface of the copper-containing substrate is initially calculated to determine the number of atoms required to be dissolved into the copper-containing substrate. Once the number of atoms required to dissolve into the copper-containing substrate is known, the thickness of the copper-containing substrate to form a graphene monolayer on the or each surface of the copper-containing substrate is then determined. If a graphene film having a depth equal to N number of monolayers is desired, the calculated thickness of the copper-containing substrate required to produce a graphene monolayer is proportionally increased by a multiple of N to obtain the required thickness of the copper-containing substrate. When the thickness of the copper-containing substrate has been determined, repetitive use of the copper-containing substrate has been found to result in consistent production of graphene films having the desired depths.

By limiting the thickness of the copper-containing substrate, it is also possible to ensure that the copper-containing substrate is sufficiently thin to allow dissolved carbon atoms to segregate and form a graphene film and thereby render the copper-containing substrate suitable for use in a carbon-segregation method.

The thickness of the copper-containing substrate may therefore be used as a reliable control parameter in controlling the depth of the resultant graphene film formed on the or each surface of the copper-containing substrate.

Furthermore, using the thickness of the copper-containing substrate as a control parameter for graphene growth obviates the need to monitor the exposure time and pressure of the carbon-containing precursor gas, or the length of time of cooling of the copper-containing substrate in real-time to control the total number of segregated atoms so as to achieve a target depth of the graphene film. This has the benefit of reducing the number of processing parameters, and thereby simplifies the method of fabricating a graphene film.

Whilst in embodiments of the invention the substrate may be formed from copper, it is envisaged that in other embodiments of the invention it could be formed from a copper-containing alloy. The substrate may, for example, be formed from a copper-nickel alloy, the incorporation of copper in the alloy resulting in the need for a thicker substrate than would otherwise be the case for a nickel substrate, thereby rendering it possible to use the thickness of the substrate to control the thickness of the resultant graphene film formed on one or more surfaces of the substrate.

The exposure temperature may be in the range of 850-1083° C. In preferred embodiments, the copper-containing substrate is exposed to the carbon-containing precursor gas at an exposure temperature of 950° C.

In order to reduce the risk of impurities in the resultant graphene film, the step of cooling the substrate to segregate the dissolved carbon atoms preferably involves cooling the substrate in an inert atmosphere. In such embodiments, the inert atmosphere may be created by exposing the substrate to an inert gas or an ultra high vacuum.

The step of cooling the substrate to segregate the dissolved carbon atoms may involve cooling the substrate to a first reduced temperature at a first rate of change of temperature before cooling the substrate to a second reduced temperature at a second rate of change of temperature, the second rate of change of temperature being greater than the first rate of change of temperature.

The solubility of carbon in copper decreases roughly from 0.004 to 0.002 weight percent between 950° C. and 800° C. Thus controlling the rate of change in temperature of the copper-containing substrate controls the rate of change in solubility of carbon in copper, which affects the rate of segregation of the dissolved carbon atoms on the or each surface.

The first rate of change of temperature is set to be sufficiently slow so as to obtain a low nucleation density and thereby large graphene flakes of high crystalline quality, while the second rate of change of temperature is set to be sufficiently fast so as to inhibit further segregation of dissolved carbon atoms on the or each surface of the copper substrate.

Preferably the first reduced temperature is in the range of 750-900° C., and is more preferably towards the lower end of this range to encourage the carbon atoms to move towards the surface of the substrate for segregation. The temperature of the substrate is preferably cooled from the exposure temperature to the first reduced temperature as slowly as possibly so as to segregate the dissolved carbon atoms at the desired rate and thereby ensure the production of high quality graphene, the first rate of change of temperature being within the range of 5° C. per minute and 10° C. per minute, and preferably within the range of 5° C. per minute.

Graphene stops growing at a temperature of approximately 450° C. and so the second reduced temperature is preferably less than 450° C. so as to stop the formation of graphene, and is more preferably ambient room temperature.

The method may further include the step of cleaning the substrate by means of ion erosion prior to the step of heating the substrate to the exposure temperature in order to remove any impurities from the surface of the substrate.

In other embodiments the step of heating the substrate to the exposure temperature may involve annealing the temperature at an annealing temperature, which is greater than the exposure temperature, and then cooling the substrate to the exposure temperature. In such embodiments, the additional step of annealing the substrate acts to remove any impurities from the surface of the substrate. In such embodiments, the annealing temperature is preferably 1000° C.

The method preferably includes the step of removing non-dissolved carbon atoms from the or each surface of the substrate prior to the step of cooling the substrate so as to segregate the dissolved carbon atoms. In such embodiments the step of removing non-dissolved carbon atoms may involve sputtering the non-dissolved carbon atoms from the or each surface.

The exposure of the copper-containing substrate to the carbon-containing precursor gas not only results in carbon atoms being dissolved into the copper substrate, but may also results in non-dissolved carbon atoms being absorbed on the or each surface of the copper-containing substrate. The presence of non-dissolved carbon atoms on the surface of the substrate however may result in an uneven graphene film on the or each surface upon segregation of the dissolved carbon atoms. Removing the non-dissolved carbon atoms from the or each surface of the substrate ensures that the mechanism for graphene growth on the or each surface is solely through carbon segregation and thereby improves the quality of the resultant graphene film.

During cooling of the substrate so as to segregate the dissolved carbon atoms, the substrate may be cooled on one side only so as to create a temperature gradient across the width of a surface of the substrate. The resultant temperature gradient results in selective growth of the graphene film during cooling of the substrate whereby graphene growth initially occurs at the cooler end of the temperature gradient before advancing towards the warmer end of the temperature gradient.

In such embodiments the substrate may be shaped so that the surface of the substrate tapers in depth across its width and the substrate is cooled so that the shallower side of the surface is at a lower temperature than the deeper side of the surface. Shaping the substrate in this manner allows a relatively small graphene flake to be grown at the shallower side to provide a seed to aid subsequent growth of larger domains of graphene of high crystalline quality on the surface.

In order to vary the depth of the resultant graphene film, the substrate may be formed to define first and second opposing surfaces, the first surface being a surface and the second surface defining steps. In such embodiments the depth of the resultant graphene film across the first, surface is determined by the depth of the substrate relative to the first surface at each step of the second surface. Thus, the provision of a stepped, second surface allows the formation of a graphene film having a variable, controlled depth on the first surface. This may be used to form three-dimensional graphene structures, if desired, to a high degree of precision.

In yet further embodiments of the invention, the quality of the resultant graphene film may be improved through the use of a substrate defining first and second opposed surfaces and exposing only the first surface to a carbon-containing gas whilst the second surface is exposed to an inert atmosphere. In such embodiments, the inert atmosphere may be created by exposing the other of the first and second opposed surfaces to an inert gas or an ultra high vacuum.

In such embodiments the step of cooling the substrate to segregate the dissolved carbon atoms from the substrate may result in the formation of graphene film on both the first and second opposed surfaces of the substrate. The graphene film formed on the second surface however is created by carbon atoms dissolved into the substrate via the first surface and segregated on the second surface, the substrate thereby effectively acting as a filter to remove any impurities and ensure the formation of a high quality graphene film on the second surface of the substrate.

Preferred embodiments of the invention will now be described, by way of non-limiting examples, with reference to the accompanying drawings in which:

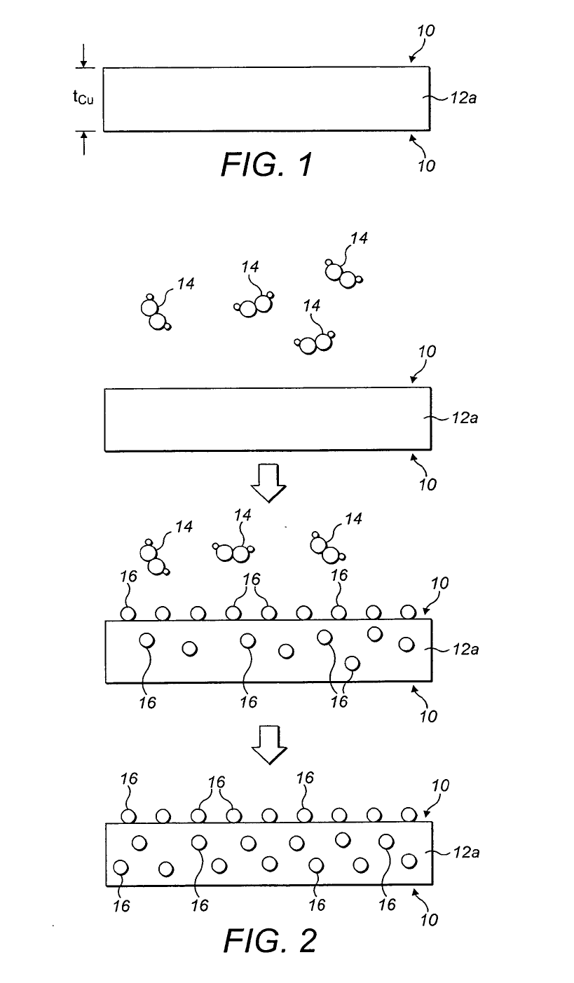

FIG. 1 shows a copper substrate for use in a first embodiment of the method according to the invention;

FIG. 2 illustrates the decomposition of acetylene molecules during exposure of the copper substrate of FIG. 1 to acetylene;

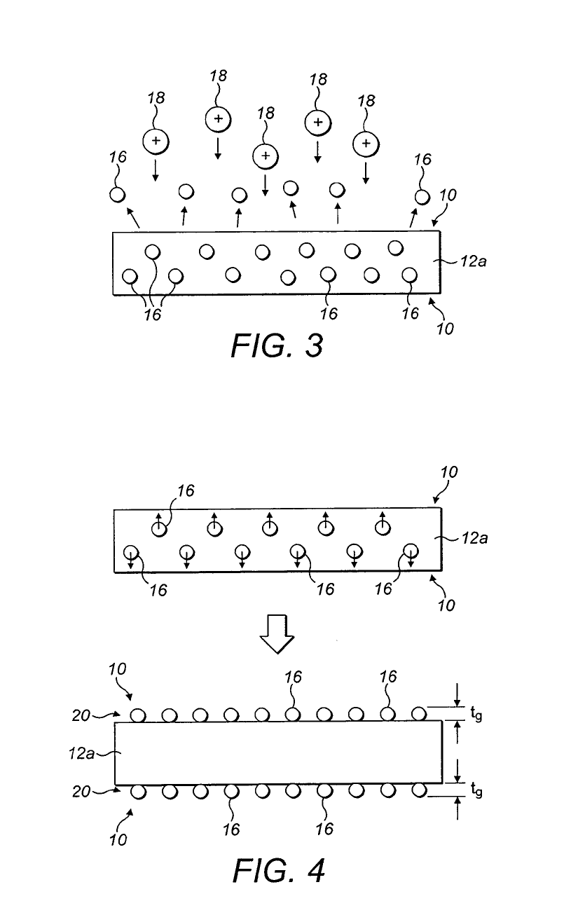

FIG. 3 illustrates the cleaning of the planar surfaces of the copper substrate of FIG. 1 using ion sputtering;

FIG. 4 illustrates the segregation of dissolved carbon atoms to form a graphene film on the planar surfaces of the copper substrate of FIG. 1;

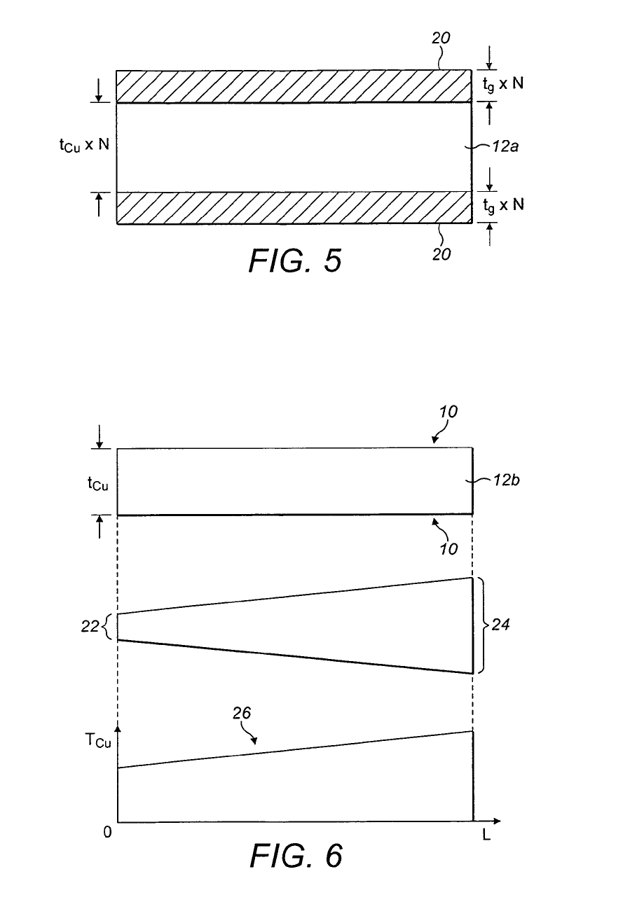

FIG. 5 illustrates the relationship between the thickness t_{Cu} of the copper substrate and the depth t_{g} of the graphene film formed on the planar surfaces of the copper substrate of FIG. 1;

FIG. 6 shows a copper substrate for use in a second embodiment of the method according to the invention;

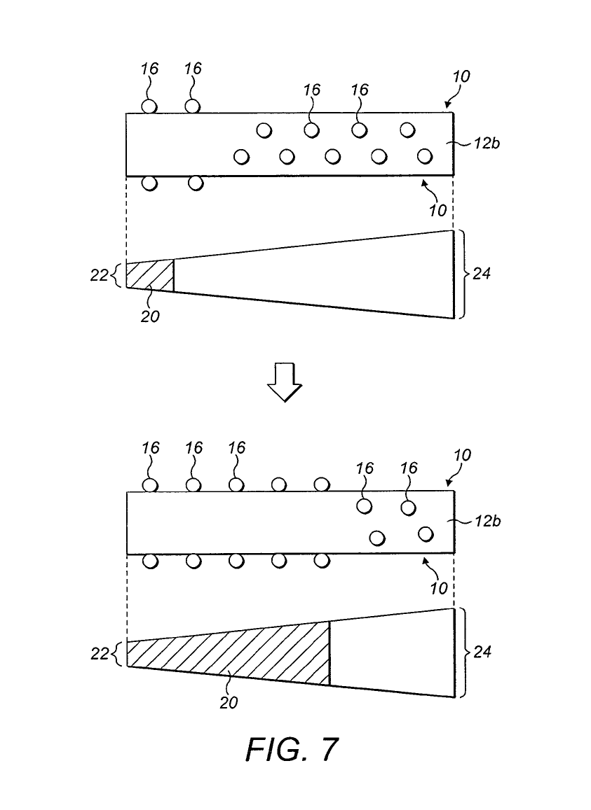

FIG. 7 illustrates the formation of the graphene film during cooling of the copper substrate of FIG. 6;

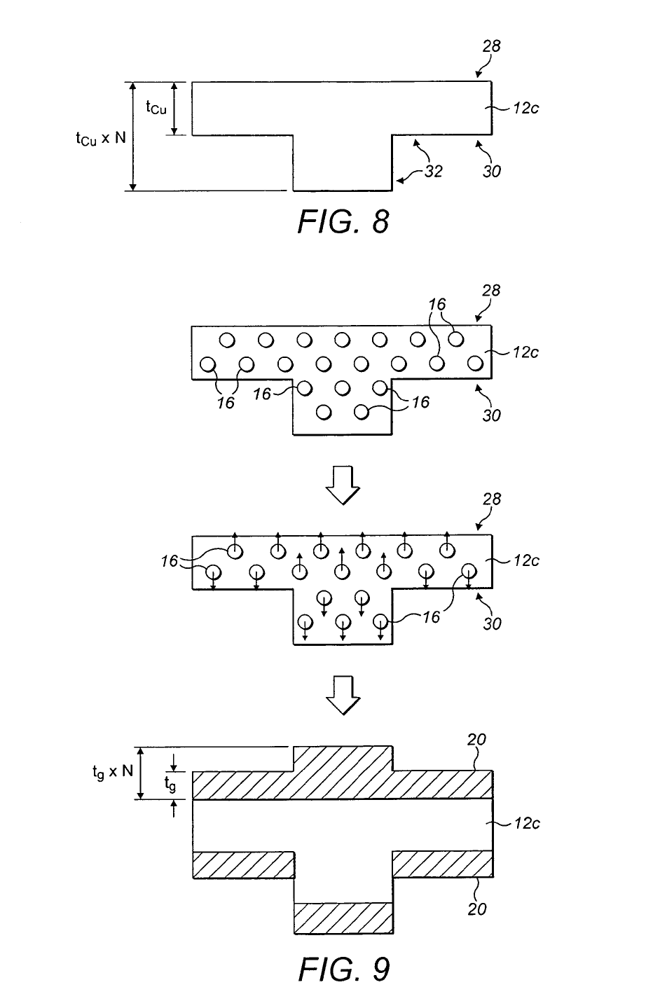

FIG. 8 shows a copper substrate for use in a third embodiment of the method according to the invention; and

FIG. 9 illustrates the formation of the graphene film during cooling of the copper substrate of FIG. 8;

A first method of forming a graphene film on planar surfaces 10 of a copper substrate 12a is described as follows with reference to FIGS. 1 to 4.

Firstly, a copper substrate 12a is selected. The copper substrate 12a defines two opposite, planar surfaces 10, which are identical in shape and are separated by a predefined thickness t_{Cu}, as shown in FIG. 1.

It is envisaged that in other embodiments a substrate formed from a copper-containing alloy may be used. The substrate may, for example, be formed from a copper-nickel alloy exhibiting the required lattice structure.

The copper substrate 12a is then annealed in hydrogen gas at a temperature of 1000° C., which is below the melting temperature of copper. The purpose of annealing the copper substrate 12a in hydrogen gas is to remove impurities and fix defects in the copper substrate 12a. This is followed by removal of the hydrogen gas and cooling of the copper substrate 12a to 950° C.

In other embodiments, the step of annealing the copper substrate 12a may be omitted. Any impurities may instead be removed by means of ion erosion before heating the copper substrate 12a to 950° C. In yet further embodiments a step of removing any impurities may be omitted entirely.

The copper substrate 12a is then exposed to acetylene, C₂H₂ at 950° C. for 10 minutes, which results in the absorption of C₂H₂ molecules 14 on the planar surfaces 10 of the copper substrate 12a. FIG. 2 shows the decomposition of the absorbed C₂H₂ molecules 14 to form carbon atoms 16 and volatile components. The carbon atoms 16 either remain on the planar surfaces 10 or dissolve into the copper substrate 12a, while the volatile components are pumped away using a vacuum pumping system. The high diffusion coefficient of carbon in copper results in a homogeneous distribution of the dissolved carbon atoms 16 within the copper substrate 12a.

The length of time of exposure of the copper substrate 12a to acetylene is determined by calculating the number of carbon atoms 16 that can be dissolved into the copper substrate 12a at 950° C., and then calculating the time it takes for that number of carbon atoms 16 to be dissolved into and homogeneously distributed within the copper substrate 12a to saturate the copper substrate 12a with carbon atoms 16.

It is envisaged that, in other embodiments, acetylene may be replaced by another carbon-containing precursor gas.

The acetylene gas is then removed and the copper substrate is exposed to argon gas to create an inert atmosphere and thereby prevent contamination of the planar surfaces 10 of the copper substrate 12a.

It is envisaged that in other embodiments an inert atmosphere may be created by exposing the copper substrate 12a to an ultra high vacuum.

In yet further embodiments the inert atmosphere may not be required. This is because the creation of a monolayer of graphene on each of the planar surfaces 10 of the copper substrate 12a will protect the planar surfaces 10 and prevent contamination.

At this stage sputtering using accelerated ions 18 is used to remove the non-dissolved carbon atoms 16 from the planar surfaces 10 of the copper substrate 12a, as shown in FIG. 3. This step may be omitted if the planar surfaces 10 of the copper substrate 12a are free of non-dissolved carbon atoms 16.

Once ion sputtering of the planar surfaces 10 is complete, the copper substrate 12a is then cooled in the argon gas to 800° C. at a rate of 5° C. per minute. As described earlier, the solubility of carbon in copper changes from 0.004 weight percent at 950° C. to 0.002 weight percent at 800° C. The reduction in solubility of carbon causes the dissolved carbon atoms 16 to diffuse through the copper substrate 12a and segregate to form a graphene film 20 on both planar surfaces 10 of the copper substrate 12a. The homogeneous and uniform distribution of dissolved carbon atoms 16 within the copper substrate 12a means that the dissolved carbon atoms 16 segregate in equal amounts at both planar surfaces 10 of the copper substrate 12a. This results in a uniform growth of the graphene film 20 on both planar surfaces 10 of the copper substrate 12a, as shown in FIG. 4.

The high diffusion coefficient of carbon in copper, 3×10⁻¹¹ m²s⁻¹ at 870° C., allows the graphene film 20 to be rapidly formed, while cooling the copper substrate 12a at a cooling rate of 5° C. per minute results in a low nucleation density, which encourages the formation of large graphene flakes of high crystalline quality.

The dissolved carbon atoms 16 continue to segregate on the planar surfaces 10 of the copper substrate 12a until the temperature of the copper substrate 12a reaches 800° C. The copper substrate 12a is then cooled rapidly, at a rate of more than 10° C. per minute, to ambient temperature to inhibit further segregation of dissolved carbon atoms 16 on the planar surfaces 10 of the copper substrate 12a, since graphene growth through carbon segregation only occurs at temperatures above 750° C.

Finally, the newly formed graphene film 20 is removed from the planar surfaces 10 of the copper substrate 12a. Removal of the graphene film 20 may be carried out by, for example, using adhesive tape to extract the graphene film or by dissolving the copper substrate 12a to leave a free-standing graphene film.

As described earlier, the depth t_{g} of the resultant graphene film 20 formed on the planar surfaces 10 of the copper substrate 12a is determined by the thickness t_{Cu} of the copper substrate 12a. Since the graphene film 20 is formed on both planar surfaces 10 of the copper substrate 12a and the structure of graphene means that there are 2 carbon atoms per copper atom at each planar surface 10, it is calculated that a value of approximately 282 microns for t_{Cu} is required to dissolve sufficient carbon atoms 16 to form a graphene monolayer 16 on both planar surfaces 10. On this basis, the thickness t_{Cu} of the copper substrate 12a may be defined to be equal to 282×N microns to form a graphene film 16 having a depth t_{g} equal to N graphene monolayers on the planar surfaces 10 of the copper substrate 12a, as shown in FIG. 5.

An advantage of using the thickness t_{Cu} of the copper substrate 12a as a control parameter to determine the depth t_{g} of the graphene film 20 is that it removes the need to control the length of time of cooling the substrate 12a so as to control the amount of segregated carbon atoms 16 and thereby the depth of the graphene film 20. This in turn allows the use of a slow rate of change of temperature when cooling the copper substrate 12a to obtain a graphene film 20 of high crystalline quality. Otherwise, if the length of time of cooling the copper substrate 12a is used to determine the depth t_{g} of the resultant graphene film 16, it would be necessary to adjust the rate of change of temperature used to cool the substrate 12a to achieve a specific depth of the resultant graphene film 16. Consequently the rate of change of temperature may become high enough to prevent a low nucleation density and thereby the manufacture of graphene of high crystalline quality.

It will be appreciated that the temperatures identified in the embodiment described with reference to FIGS. 1 to 5 may vary depending on the composition of the substrate.

It will also be appreciated that the thickness of the substrate t_{Cu} required to generate a monolayer of graphene on opposing planar surfaces of the substrate may vary depending on the composition of the substrate.

In other embodiments, the quality of graphene may be improved by exposing only one of the planar surfaces 10 of the copper substrate 12a to acetylene whilst the other planar surface 10 is exposed to an inert atmosphere.

In such embodiments the inert atmosphere may be created through the use of an inert gas, such as argon, or by the use of an ultra high vacuum.

As in the embodiment described with reference to FIGS. 1 to 5, graphene film 20 will be formed on both planar surfaces 10 of the copper substrate 12a on cooling the copper substrate 12a to segregate the dissolved carbon atoms 16.

It will be appreciated that the graphene film 20 will form on the planar surface 10 that was exposed to an inert atmosphere during saturation of the copper substrate 12a with carbon atoms 16. The carbon atoms 16 that segregate onto this surface 10 during such methods will have diffused through the copper substrate 12a from the planar surface 10 exposed to the carbon-containing precursor gas, the copper substrate 12a thereby acting as a filter to remove any impurities that might otherwise affect the quality of the graphene film 20 formed on this planar surface 10.

Another embodiment of a method of forming a graphene film on planar surfaces of a copper substrate is described, as follows, with reference to FIGS. 6 to 8.

The second embodiment of the method is identical to the first method, except that, as shown in FIG. 6:
the planar surfaces 10 of the copper substrate 12b are shaped to taper in width from one side 22 to the other side 24, i.e. one side 22 is narrower than the other side 24; and
after ion sputtering of the planar surfaces 10 is completed, a temperature gradient 26 is applied lengthwise to the copper substrate 12b such that the narrower side 22 of the planar surfaces 10 is at a lower temperature than the opposite, wider side 24.

FIG. 7 illustrates the formation of the graphene film 20 during cooling of the copper substrate 12b of FIG. 6.

During cooling of the copper substrate 12b, segregation of the dissolved carbon atoms 16 initially occurs towards the narrower, cooler side 22 to form a graphene flake 20 on each planar surface 10, while there is no segregation of dissolved carbon atoms 16 towards the wider, warmer side 24. When the copper substrate 12b is sufficiently cooled to allow segregation of dissolved carbon atoms 16 towards the wider side 24 of the planar surfaces 10, the graphene flake 20 initially formed at the narrower side 22 acts as a seed, i.e. nucleation site, to aid subsequent graphene growth towards the wider side 24 of the planar surfaces 10. This results in the formation of large domains of graphene of high crystalline quality.

The third embodiment of the method is identical to the first method, except that, as shown in FIG. 8, the copper substrate 12c includes first and second opposing surfaces 28,30, the first surface 28 being a planar surface and the second surface 30 defining steps 32 so as to vary the depth of the substrate 12c relative to the first surface 28.

FIG. 9 illustrates the formation of the graphene film during cooling of the copper substrate of FIG. 8.

During cooling of the copper substrate 12c, the homogeneous and uniform distribution of dissolved carbon atoms 16 within the copper substrate 12c results in the formation of the graphene film 20 on both the first and second opposing surfaces 28,30 of the copper substrate 12c.

The depth of the graphene film 20 formed on the first and second surfaces 28,30 is determined by the depth of the substrate 12c relative to the first surface 28 at each step 32 of the second surface 30. This, together with the planarity of the first surface 28, results in the formation of a continuous graphene film 20 having a variable depth across the first planar surface 28. The provision of a stepped, second surface 30 therefore allows the formation of a graphene film 20 having a variable, controlled depth on the first planar surface 30. This feature is particularly beneficial when it comes to forming three-dimensional graphene structures.

It is further envisaged that, in other embodiments, a graphene film may be manufactured in accordance with a combination of two or more of the above-described methods of forming a graphene film on one or more planar surfaces of a copper substrate.

1. A method of forming a graphene film on one or more surfaces of a copper-containing substrate comprising the steps of:
(i) heating a copper-containing substrate defining one or more surfaces to an exposure temperature;
(ii) exposing the substrate to a carbon-containing precursor gas at the exposure temperature for a predetermined period of time to dissolve carbon atoms into the substrate and saturate the substrate with carbon atoms; and
(iii) cooling the substrate so as to segregate the dissolved carbon atoms from the substrate to form a graphene film on the or each surface of the substrate;
wherein the method further includes the step of selecting the copper-containing substrate on the basis of its thickness to control the depth of the graphene film formed on the or each surface of the substrate on cooling the substrate so as to segregate the dissolved carbon atoms from the substrate.

2. A method of forming a graphene film according to claim 1 wherein the copper-containing substrate is formed from copper or a copper-containing alloy.

3. A method of forming a graphene film according to claim 1 wherein the exposure temperature is in the range of 850-1083° C.

4. A method of forming a graphene film according to claim 3 wherein the exposure temperature is 950° C.

5. A method of forming a graphene film according to claim 1 wherein the step of cooling the substrate to segregate the dissolved carbon atoms involves cooling the substrate in an inert atmosphere.

6. A method of forming a graphene film according to claim 5 wherein the inert atmosphere is created by exposing the substrate to an inert gas or an ultra high vacuum.

7. A method of forming a graphene film according to claim 1 wherein the step of cooling the substrate to segregate the dissolved carbon atoms involves cooling the substrate to a first reduced temperature at a first rate of change of temperature before cooling the substrate to a second reduced temperature at a second rate of change of temperature, the second rate of change of temperature being greater than the first rate of change of temperature.

8. A method of forming a graphene film according to claim 7 wherein the first reduced temperature is in the range of 750-900° C. and the second reduced temperature is less than 450° C.

9. A method of forming a graphene film according to claim 7 wherein the first reduced temperature is 800° C. and the second reduced temperature is ambient room temperature.

10. A method of forming a graphene film according to claim 7 wherein the first rate of change of temperature is in the range of 5° C. per minute-10° C. per minute.

11. A method of forming a graphene film according to claim 1 claims further including the step of cleaning the substrate by means of ion erosion prior to the step of heating the substrate to the exposure temperature.

12. A method of forming a graphene film according to claim 1 wherein the step of heating the substrate to the exposure temperature involves annealing the substrate in hydrogen gas at an annealing temperature, which is greater than the exposure temperature, and then cooling the substrate to the exposure temperature.

13. A method of forming a graphene film according to claim 12 wherein the annealing temperature is 1000° C.

14. A method of forming a graphene film according to claim 1 further including the step of removing non-dissolved carbon atoms from the or each surface of the substrate prior to the step of cooling the substrate so as to segregate the dissolved carbon atoms.

15. A method of forming a graphene film according to claim 14 wherein the step of removing non-dissolved carbon atoms involves sputtering the non-dissolved carbon atoms from the or each surface.

16. A method of forming a graphene film according to claim 1 wherein the step of cooling the substrate so as to segregate the dissolved carbon atoms involves cooling the substrate on one side only so as to create a temperature gradient across the width of a surface of the substrate.

17. A method of forming a graphene film according to claim 16 wherein the substrate is shaped so that the surface of the substrate tapers in depth across its width and the substrate is cooled so that the shallower side of the surface is at a lower temperature than the deeper side of the surface.

18. A method according to claim 1 wherein the substrate defines first and second opposing surfaces, the first surface being a planar surface and the second surface defining steps so as to vary the depth of the substrate relative to the first surface.

19. A method according to claim 1 wherein the substrate defines first and second opposing surfaces and the step of exposing the substrate to a carbon-containing precursor gas involves exposing only the first opposing surface to the carbon-containing precursor gas whilst the second opposing surface is exposed to an inert atmosphere.

20. A method according to claim 19 wherein the inert atmosphere is created by exposing the second opposing surface of the substrate to an inert gas or an ultra high vacuum.
